(19) United States
(12) Patent Application Publication
(10) Pub. No.: US 2017/0325010 A1
(43) Pub. Date: Nov. 9, 2017

(54) Amplifier Structure

(71) Applicant: CHIA YO ELECTRONICS CO., LTD., Chiayi City (TW)

(72) Inventor: Te-Wei Kung, Chiayi City (TW)

(21) Appl. No.: 15/149,604

(22) Filed: May 9, 2016

(51) Int. Cl. H04R 1/02; G06F 3/16; H03F 3/181

(52) U.S. Cl. CPC H04R 1/02; H03F 3/181; G06F 3/162; H04R 2420/01; H03F 2200/03

(57) ABSTRACT

An amplifier structure contains an amplifier, and the amplifier includes: a body and a cover rotatably connected with one end of the body. The body includes an inner housing fence defined on the body relative to the cover and configured to house a plurality of charging holders for accommodating multiple wireless microphones respectively. The amplifier further includes an accommodation chamber formed in the inner housing fence. When a power source supplies power to the amplifier via an electric wire, the plurality of charging holders charges the power to the multiple wireless microphones individually.

### BACKGROUND OF THE INVENTION

### Field of the Invention

The present invention relates to an amplifier structure which contains an amplifier, and the amplifier includes a plurality of charging holders for accommodating multiple wireless microphones respectively and includes an accommodation chamber, such that a power source supplies power to the plurality of charging holders via an electric wire of the amplifier or at least one battery, and the plurality of charging holders charge the power to the multiple wireless microphones individually.

### Description of the Prior Art

Conventional microphone mates with an amplifier so as to amplify sounds from the microphone, so user carries the amplifier with one hand and grasps the microphone with the other hand (so as to move among classrooms in a school), hence the user cannot takes other objects with two hands any more.

When the microphone is a wireless microphone, it is essential for the user to charge power to the wireless microphone. In other words, when the wireless microphone runs out of the power, other new microphones replace the wireless microphone, thus increasing carrying inconvenience because the amplifier cannot accommodate at least one wireless microphone, and the at least one wireless microphone cannot be charged the power.

The present invention has arisen to mitigate and/or obviate the afore-described disadvantages.

### SUMMARY OF THE INVENTION

The primary objective of the present invention is to provide an amplifier structure which contains an amplifier, and the amplifier includes a plurality of charging holders for accommodating multiple wireless microphones respectively and includes an accommodation chamber, such that the plurality of charging holders accommodate the multiple wireless microphones respectively, and the accommodation chamber houses electric wire, power supply, other belongings, and stuffs.

Further objective of the present invention is to provide an amplifier structure in which the plurality of charging holders charges power to the multiple wireless microphones (or multiple wired microphones) individually, when a power source supplies power to the amplifier via an electric wire.

Another objective of the present invention is to provide an amplifier structure which contains at least one battery, and when the amplifier connects with the power supply via the electric wire, the power supply supplies the power to the at least one battery and the plurality of charging holders, after the electric wire is removed, the at least one battery supplies the power to the plurality of charging holders, thus charging the power to the multiple wireless microphones quickly as carrying or storing the amplifier.

To obtain above objectives, an amplifier structure provided by a preferred embodiment of the present invention contains an amplifier, and the amplifier includes: a body and a cover rotatably connected with one end of the body.

The body includes an inner housing fence defined on the body relative to the cover and configured to house a plurality of charging holders for accommodating multiple wireless microphones respectively, and the amplifier further includes an accommodation chamber formed in the inner housing fence, such that when a power source supplies power to the amplifier via an electric wire, the plurality of charging holders charge the power to the multiple wireless microphones individually.

### BRIEF DESCRIPTION OF THE DRAWINGS

FIG. 1 is a perspective view showing the assembly of an amplifier structure in accordance with a preferred embodiment of the present invention.

FIG. 2 is a perspective view showing the assembly of a part of the amplifier structure in accordance with the preferred embodiment of the present invention.

FIG. 3 is a perspective view showing the operation of the amplifier structure in accordance with the preferred embodiment of the present invention.

FIG. 4 is a perspective view showing the application of the amplifier structure in accordance with the preferred embodiment of the present invention.

### DETAILED DESCRIPTION OF THE PREFERRED EMBODIMENTS

The present invention will be clearer from the following description when viewed together with the accompanying drawings, which show, for purpose of illustrations only, the preferred embodiment in accordance with the present invention.

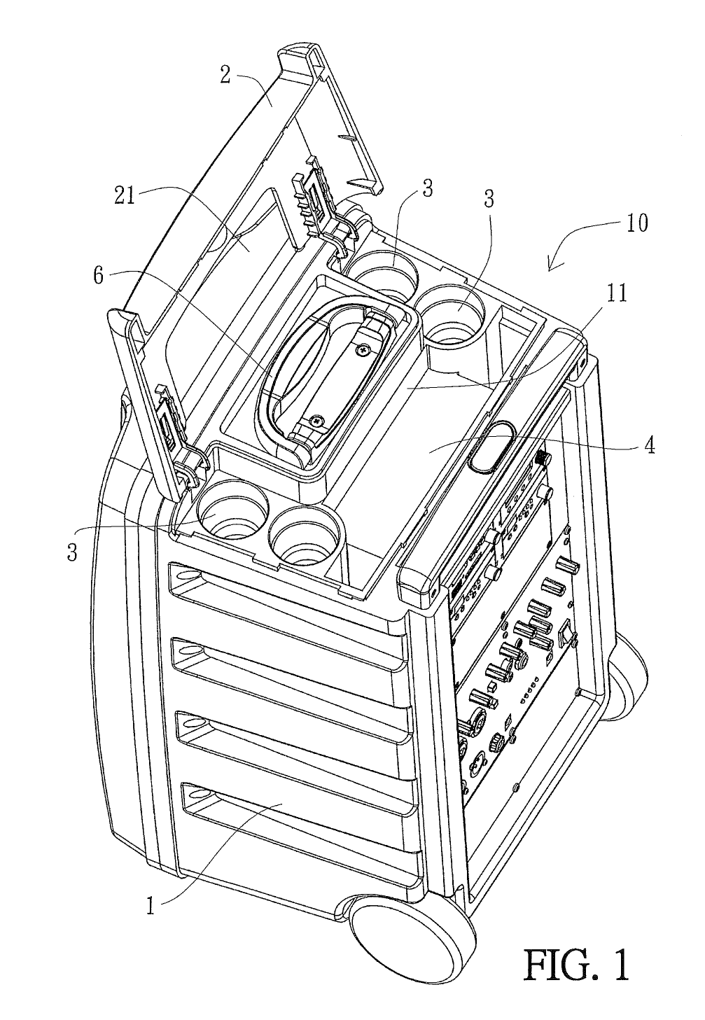

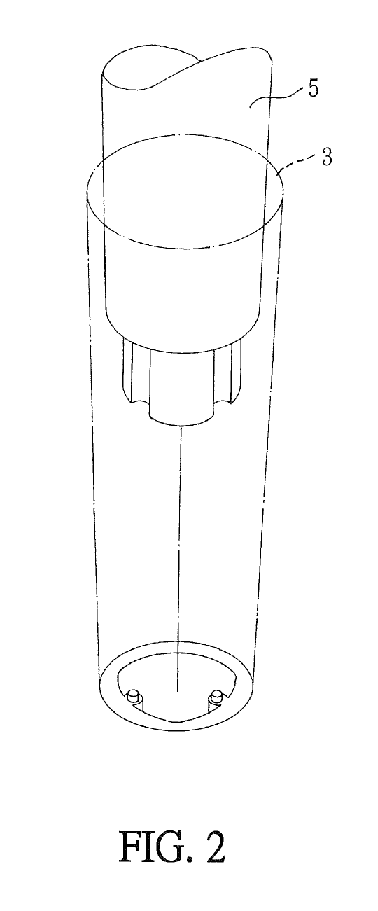

An amplifier structure according to a preferred embodiment of the present invention comprises an amplifier 10, and the amplifier 10 includes: a body 1 and a cover 2 rotatably connected with one end of the body 1 (as shown in FIG. 1), wherein the body 1 includes an inner housing fence 11 defined on the body 1 relative to the cover 2 and configured to house a plurality of charging holders 3 for accommodating multiple wireless microphones 5 respectively, and the amplifier 10 further includes an accommodation chamber 4 (as illustrated in FIG. 2) formed in the inner housing fence 11 so that when a power source supplies power to the amplifier 10 via an electric wire, the plurality of charging holders 3 charge the power to the multiple wireless microphones 5 individually.

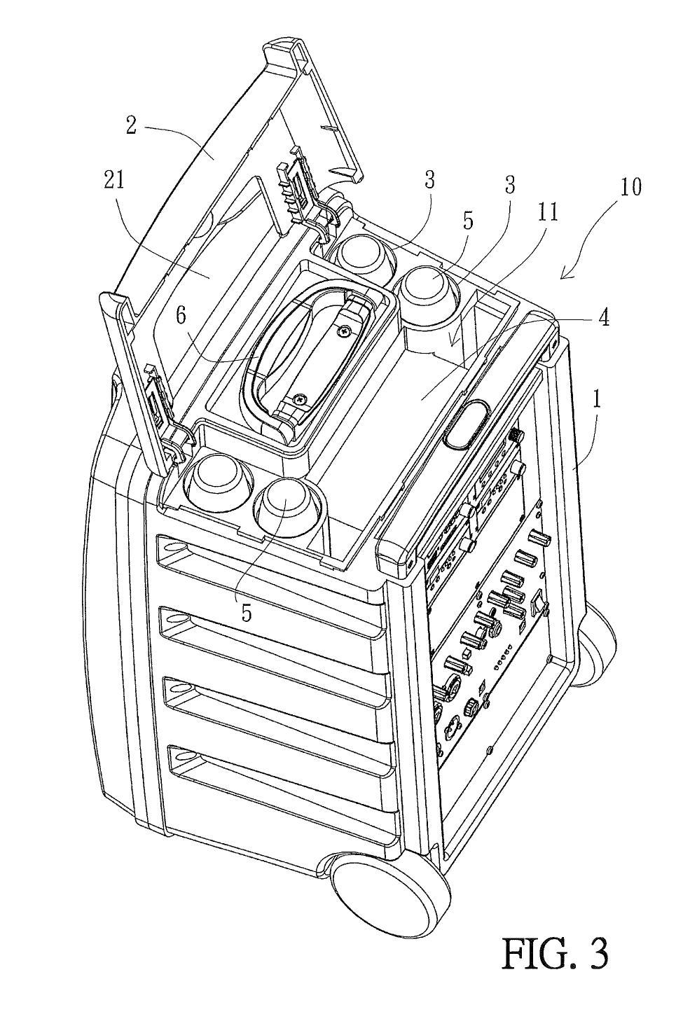

Accordingly, the body 1 of the amplifier 10 has the plurality of charging holders 3 which accommodate the multiple wireless microphones 5 individually (as shown in FIG. 3), and when the power source supplies power to the plurality of charging holders 3, the plurality of charging holders 3 charge the power to the multiple wireless microphones 5 individually, thus charging the power to the multiple wireless microphones 5 and obtaining easy storage and carrying convenience (for example, the accommodation chamber 4 houses the electric wire, power supply, other belongings, and stuffs).

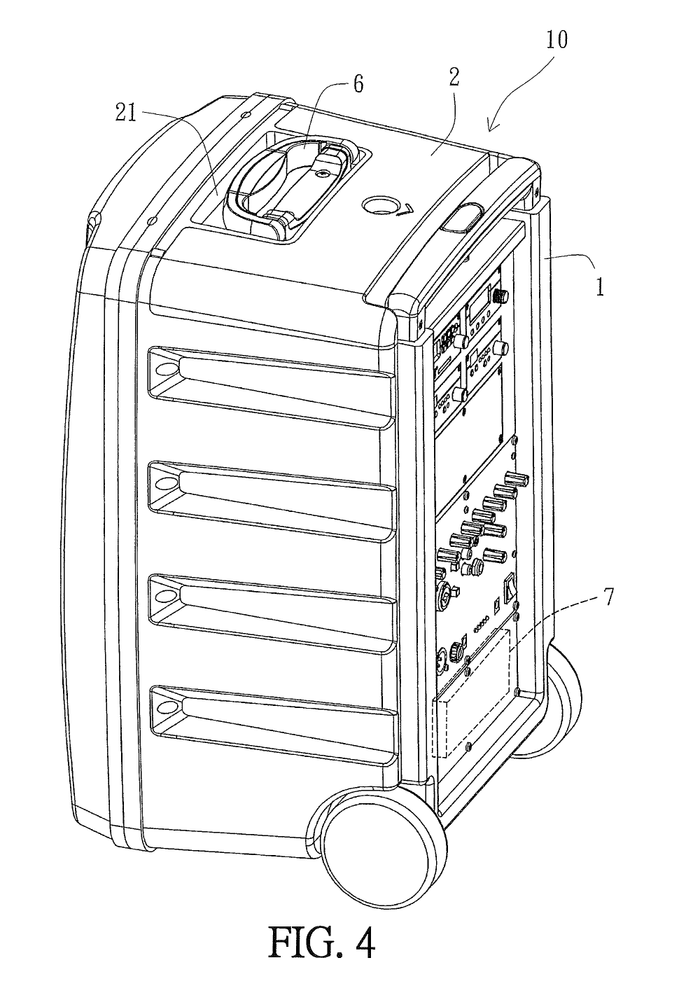

The amplifier 10 includes the cover 2 disposed on a top thereof, wherein the inner housing fence 11 has a handle bar 6 fixed thereon, and the cover 2 has a cutout 21 defined thereon and corresponding to the handle bar 6, such that after the cover 2 covers the amplifier 10, the amplifier 10 is picked up by using the handle bar 6 (as illustrated in FIG. 4).

The amplifier 10 includes at least one battery 7 mounted therein, and when the amplifier 10 connects with the power supply via the electric wire, the power supply supplies the power to the at least one battery 7 and the plurality of charging holders 3. After the electric wire is removed, the at least one battery 7 supplies the power to the plurality of charging holders 3, thus charging the power to the multiple wireless microphones 5 quickly as carrying or storing the amplifier 10.

While we have shown and described various embodiments in accordance with the present invention, it is clear to those skilled in the art that further embodiments may be made without departing from the scope of the present invention.

1. An amplifier structure comprising an amplifier; multiple wireless microphones a body; a cover rotatably connected with one end of the body between an open position and a closed position, wherein the body includes an inner housing fence defined on the body relative to the cover and housing a plurality of charging holders, with the multiple wireless microphones received in the plurality of charging holders respectively; and an accommodation chamber formed in the inner housing fence, with the multiple wireless microphones in the plurality of charging holders and the accommodating chamber being accessible when the cover is in the open position and being enclosed by the body and the cover when the cover is in the closed position, and wherein when a power source supplies power to the amplifier via an electric wire, the plurality of charging holders charges the power to the multiple wireless microphones received in the plurality of charging holders individually.

2. The amplifier structure as claimed in claim 1, further comprising at least one battery mounted in the body, and wherein when the amplifier connects with the power supply via the electric wire, the power supply supplies the power to the at least one battery and the plurality of charging holders, and after the electric wire is removed, the at least one battery supplies the power to the plurality of charging holders, thus charging the power to the multiple wireless microphones received in the plurality of charging holders.

3. The amplifier structure as claimed in claim 1, wherein the cover rotatably is connected with a top of the amplifier, the inner housing fence has a handle bar fixed thereon, the cover has a cutout defined thereon and corresponding to the handle bar in the closed position, and that after the cover covers the amplifier, the amplifier is picked up by using the handle bar.

4. The amplifier structure as claimed in claim 2, wherein the cover rotatably is connected with a top of the amplifier, the inner housing fence has a handle bar fixed thereon, the cover has a cutout defined thereon and corresponding to the handle bar in the closed position, and that after the cover covers the amplifier, the amplifier is picked up by using the handle bar.
